(19) United States
(12) Patent Application Publication
(10) Pub. No.: US 2026/0003263 A1
(43) Pub. Date: Jan. 1, 2026

(54) MASK PATTERN FORMATION METHOD AND SUBSTRATE PROCESSING METHOD

(71) Applicants: Tokyo Electron Limited, Tokyo (JP); NATIONAL UNIVERSITY CORPORATION OKAYAMA UNIVERSITY, Okayama (JP)

(72) Inventors: Shin OOWADA, Tokyo (JP); Ryuichi ASAKO, Tokyo (JP); Makoto MURAMATSU, Kumamoto (JP); Tsutomu ONO, Okayama (JP); Takaichi WATANABE, Okayama (JP)

(73) Assignees: Tokyo Electron Limited, Tokyo (JP); NATIONAL UNIVERSITY CORPORATION OKAYAMA UNIVERSITY, Okayama (JP)

(21) Appl. No.: 19/319,783

(22) Filed: Sep. 5, 2025

Related U.S. Application Data
(63) Continuation of application No. PCT/JP2024/007942, filed on Mar. 4, 2024.

(30) Foreign Application Priority Data
Mar. 13, 2023 (JP) 2023-038903

(51) Int. Cl. G03F 1/80; H01L 21/027; H01L 21/308

(52) U.S. Cl. CPC G03F 1/80; H01L 21/0271; H01L 21/308

(57) ABSTRACT

A mask pattern formation method includes applying a substance that includes a polymerizable ionic liquid to a substrate, causing a polymerization reaction of the polymerizable ionic liquid for at least a part of the substance that includes a polymerizable ionic liquid to produce a substance that include a polymeric ionic liquid on the substrate, and forming a mask pattern of the substance that includes a polymeric ionic liquid on the substrate by using the substance that includes a polymeric ionic liquid.

### CROSS-REFERENCE TO RELATED APPLICATIONS

This application is a continuation of International Application No. PCT/JP2024/007942, filed on Mar. 4, 2024, the entire contents of which are herein incorporated by reference, and which is based upon and claims the benefit of priority to Japanese Patent Application No. 2023-038903, filed on Mar. 13, 2023, the entire contents of each are herein incorporated by reference.

### FIELD

The present disclosure relates to a mask pattern formation method and a substrate processing method.

### BACKGROUND

Japanese Patent Application Publication No. 2021-092759 discloses “a resist composition that generates an acid by light exposure and changes a solubility thereof in a developer by action of the acid where the resist composition contains a base material component (A) that changes a solubility thereof in a developer by action of the acid and an ionic liquid (Z) and a solid content concentration thereof is 25% by mass or greater” and “a resist pattern formation method that has a step that forms a resist film on a support by using a resist composition as described above, a step that exposes a resist film as described previously to light, and a step that develops the resist film after light exposure as described previously to form a resist pattern”.

H. Minamimoto, et al., “Polymerization of Room-Temperature Ionic Liquid Monomers by Electron Beam Irradiation with the Aim of Fabricating Three-Dimensional Micropolymer/Nanopolymer Structures”, Langmuir 2015, 31, 4281-4289 discloses that “a novel method for fabricating microsized and nanosized polymer structures from a room-temperature ionic liquid (RTIL) on a Si substrate was developed by the patterned irradiation of an electron beam (EB)”, “an extremely low vapor pressure of the RTIL, 1-allyl-3-ethylimidazolium bis((trifluoromethane) sulfonyl)amide, allows it to be introduced into the high-vacuum chamber of an electron beam apparatus to conduct a radiation-induced polymerization in the nanoregion”, and “we prepared various three-dimensional (3D) micro/nanopolymer structures having high aspect ratios of up to 5 with a resolution of sub-100 nm”.

### SUMMARY

A mask pattern formation method according to an aspect of an embodiment includes applying a substance that includes a polymerizable ionic liquid to a substrate, causing a polymerization reaction of the polymerizable ionic liquid for at least a part of the substance that includes a polymerizable ionic liquid to produce a substance that include a polymeric ionic liquid on the substrate, and forming a mask pattern of the substance that includes a polymeric ionic liquid on the substrate by using the substance that includes a polymeric ionic liquid.

### BRIEF DESCRIPTION OF DRAWINGS

FIG. 1 is a flowchart that schematically explains an example of a substrate processing method according to an embodiment.

FIG. 2 is a flowchart that illustrates a first example of a substrate processing method according to an embodiment.

FIG. 3A is a schematic diagram that explains a first example of a substrate processing method according to an embodiment.

FIG. 3B is a schematic diagram that explains a first example of a substrate processing method according to an embodiment.

FIG. 4 is a flowchart that illustrates a second example of a substrate processing method according to an embodiment.

FIG. 5A is a schematic diagram that explains a second example of a substrate processing method according to an embodiment.

FIG. 5B is a schematic diagram that explains a second example of a substrate processing method according to an embodiment.

FIG. 6 is a flowchart that illustrates a third example of a substrate processing method according to an embodiment.

FIG. 7A is a schematic diagram that explains a third example of a substrate processing method according to an embodiment.

FIG. 7B is a schematic diagram that explains a third example of a substrate processing method according to an embodiment.

FIG. 8 is a diagram that schematically explains an example of a substrate processing system for implementing a substrate processing method according to an embodiment.

FIG. 9 is a diagram that illustrates an example of a mask pattern of a polymeric ionic liquid according to a practical example.

FIG. 10 is a diagram that illustrates an example of a mask pattern of a polymeric ionic liquid according to a practical example.

FIG. 11 is a diagram that illustrates an example of a mask pattern of a polymeric ionic liquid according to a practical example.

FIG. 12 is a diagram that illustrates an example of a mask pattern of a polymeric ionic liquid according to a practical example.

FIG. 13 is a diagram that illustrates an example of LERs of a mask pattern according to a practical example and a mask pattern according to a comparative example.

FIG. 14 is a diagram that illustrates an example of a hardware configuration of a computer that composes a control device that is included in a substrate processing system.

### DESCRIPTION OF EMBODIMENTS

Hereinafter, a mode(s) (that will be described as “an embodiment(s)” below) for implementing a mask pattern formation method and a substrate processing method according to the present disclosure will be explained in detail with reference to the drawing(s). Additionally, the present disclosure is not limited by such an embodiment(s). Furthermore, it is possible to combine respective embodiments appropriately as long as process contents thereof are not inconsistent. Furthermore, in respective embodiments as provided below, an identical site will be provided with an identical sign so as to omit a redundant explanation(s) thereof.

Meanwhile, in a case where a semiconductor device that has a fine structure is fabricated, reducing a roughness of a side wall of a pattern that is produced in a lithography process is needed in order to reduce a dimension error of such a semiconductor device. For a roughness of a side wall of a pattern, a line edge roughness (LER), a line width roughness (LWR), etc., is/are used. For example, in a case where a critical dimension (CD) in semiconductor device fabrication is several tens of nanometers, an LER is several nanometers.

For example, as a wavelength of a resist light exposure light source that is used in a lithography process is reduced, it is possible to improve a resolution and a contrast of light exposure on a resist, so that it is considered that it is possible to reduce an LER. However, as a wavelength of a light exposure light source is reduced without increasing a dose amount of such a light exposure light source in order to avoid an increase of a light exposure cost, a number of a photon(s) per unit area on a resist surface that is irradiated with light is reduced. As a result, a deviation of a number of a photon(s) on a resist surface is increased, so that an LER is increased. In particular, in a case where extreme ultraviolet (EUV) light exposure is executed, an LER is not readily reduced.

Furthermore, for example, in a case where a conventional-type chemical-amplification-type resist is used, a non-uniform distribution(s) of a component(s) such as a photo-acid generating agent and/or a quencher that is/are included in such a chemical-amplification-type resist is readily provided locally, so that a deviation of a number of a photon(s) per unit area on a resist surface is readily emphasized. As a result, an LER is readily increased.

Hence, the present disclosure provides a technique that is capable of reducing a roughness of a mask pattern, such as an LER.

### Substrate Processing Method

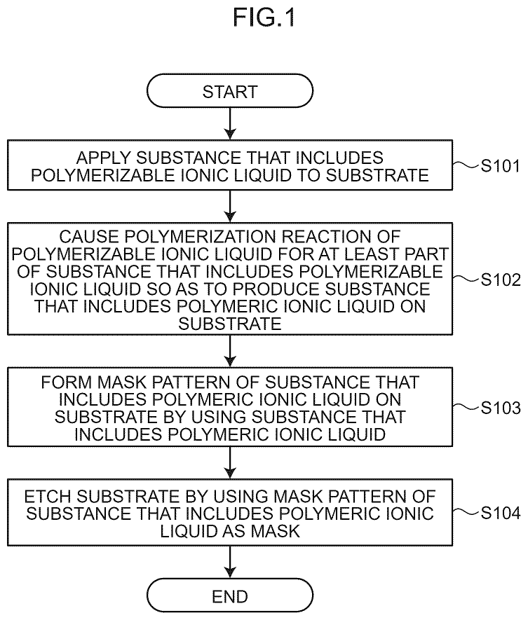

FIG. 1 is a flowchart that schematically explains an example of a substrate processing method according to an embodiment. In a substrate processing method according to an embodiment, first, a substance that includes a polymerizable ionic liquid is applied to a substrate at step S101 as illustrated in FIG. 1.

A substrate may be provided with an etching target film that is provided as a target for etching. In a case where a substrate is provided with an etching target film, a substance that includes a polymerizable ionic liquid is applied to such an etching target film. For example, a substrate may be a silicon (Si) wafer. Furthermore, an etching target film may be, for example, a film of silicon oxide (SiO₂) in order to provide a film with an insulation property.

A polymerizable ionic liquid is a liquid salt that is composed of ions that are composed of a cation and an anion where one of such a cation and an anion is a monomer. For example, in a case where a cation is a monomer, for example, a cation component and an anion component as disclosed in Japanese Patent Application Publication No. 2007-042531, etc., are provided as such a cation and an anion. Furthermore, an ionic liquid monomer that is represented by general formula (A) as disclosed in Japanese Patent Application Publication No. 2021-042150, etc., is/are provided as a polymerizable ionic liquid.

For example, a substance that includes a polymerizable ionic liquid may be composed of a polymerizable ionic liquid. Furthermore, for example, a substance that includes a polymerizable ionic liquid may include a polymerizable ionic liquid and a solvent for such a polymerizable ionic liquid. A solvent is not particularly limited as long as it is possible to dissolve a polymerizable ionic liquid.

For a method that applies a substance that includes a polymerizable ionic liquid to a substrate, for example, a spin coating method, etc., is/are provided. In a case where a substance that includes a polymerizable ionic liquid is applied to a substrate by spin coating, it is possible to apply such a substance that includes a polymerizable ionic liquid to such a substrate more uniformly.

Then, a polymerization reaction of a polymerizable ionic liquid is caused for at least a part of a substance that includes such a polymerizable ionic liquid so as to produce a substance that includes a polymeric ionic liquid on a substrate, at step S102 as illustrated in FIG. 1. Causing a polymerization reaction of a polymerizable ionic liquid for at least a part of a substance that includes such a polymerizable ionic liquid means that a monomer that is included in a polymerizable ionic liquid causes a polymerization reaction thereof for a whole or a part of such a substance that includes a polymerizable ionic liquid. Thereby, a polymeric ionic liquid is produced.

A polymeric ionic liquid is an ionic liquid that is composed of an ion that is included in a polymer that is produced by a polymerization reaction of a monomer that is included in a polymerizable ionic liquid, and an ion that does not have a polymerization property. For example, in a case where a monomer that is included in a polymerizable ionic liquid is a cation, an ionic liquid may be provided that is composed of a polymer that includes a divalent group of such a cation and an anion that is included in such a polymerizable ionic liquid, as repeating units.

A monomer may be incorporated in a main chain of a polymer by a polymerization reaction. Furthermore, a monomer may be incorporated in a side chain of a polymer by a polymerization reaction. For example, in a case where a polymerization reaction is caused for an ionic liquid monomer that is represented by general formula (A) as disclosed in Japanese Patent Application No. 2021-042150, a cation component that is included in general formula (A) is incorporated in a main chain of a polymer. For example, in a case where a polymerization reaction is caused for a cation component as disclosed in Japanese Patent Application Publication No. 2007-042531, such a cation component is incorporated in a side chain of a polymer.

In a case where a substance that includes a polymerizable ionic liquid is composed of a polymerizable ionic liquid, a substance that includes a polymeric ionic liquid may be composed of a polymeric ionic liquid. In a case where a substance that includes a polymerizable ionic liquid includes a polymerizable ionic liquid and a solvent for such a polymerizable ionic liquid, a substance that includes a polymeric ionic liquid may include a polymeric ionic liquid and a solvent as described above. In a case where a substance that includes a polymeric ionic liquid includes a solvent as described above, such a substance that includes a polymeric ionic liquid may be a gel-like substance.

For a method that causes a polymerization reaction of a polymerizable ionic liquid for a substance that includes a polymerizable ionic liquid, heating a substance that includes a polymerizable ionic liquid, irradiating a substance that includes a polymerizable ionic liquid with light, irradiating a substance that includes a polymerizable ionic liquid with an electron beam, etc., is/are provided. In a case where a substance that includes a polymerizable ionic liquid is irradiated with light or an electron beam, it is possible to cause a polymerization reaction of a polymerizable ionic liquid more readily in a selective area in such a substance that includes a polymerizable ionic liquid. That is, it is possible to produce a substance that includes a polymeric ionic liquid more readily in a selective area on a substance that includes a polymerizable ionic liquid.

Then, a mask pattern of a substance that includes a polymeric ionic liquid is formed on a substrate by using such a substance that includes a polymeric ionic liquid, at step S103 as illustrated in FIG. 1. A polymeric ionic liquid has a non-volatility and a heat resistance, so that it is possible to utilize a substance that includes a polymeric ionic liquid in order to form a mask pattern. A specific example(s) of a method that forms a mask pattern of a substance that includes a polymeric ionic liquid on a substrate by using such a substance that includes a polymeric ionic liquid will be described later.

A mask pattern of a substance that includes a polymeric ionic liquid is formed by using such a substance that includes a polymeric ionic liquid, so that it is possible to reduce a roughness of such a mask pattern such as an LER. When a mask pattern of a substance that includes a polymeric ionic liquid is formed, a damage(s) or an irregularity(ies) may be produced on a surface of such a mask pattern. Herein, a polymeric ionic liquid has a self-restoring property in such a manner that a cut polymer chain is restored by re-formation of an ionic bond between an ion that is included in a polymer and an ion that is not included in such a polymer. It is considered that, due to such a self-restoring property of a polymeric ionic liquid, a polymer chain(s) near a damage(s) or an irregularity(ies) on a surface of a mask pattern is/are restored, so that a damage(s) or an irregularity(ies) on a surface of a mask pattern of a substance that includes a polymeric ionic liquid is/are reduced. As a result, it is considered that a roughness of a mask pattern is reduced.

Thus, a substrate processing method according to an embodiment includes a mask pattern formation method that includes step S101, step S102, and step S103 as illustrated in FIG. 1.

Then, a substrate is etched by using a mask pattern of a substance that includes a polymeric ionic liquid as a mask, at step S104 as illustrated in FIG. 1. In a case where a substrate is provided with an etching target film, such an etching target film that is provided on such a substrate is etched. In a case where a substrate is not provided with an etching target film, such a substrate is etched. A specific example(s) of a method that etches a substrate by using a mask pattern of a substance that includes a polymeric ionic liquid as a mask will be described later. Additionally, only step S101, step S102, and step S103 may be executed without executing step S104.

### First Example of Substrate Processing Method

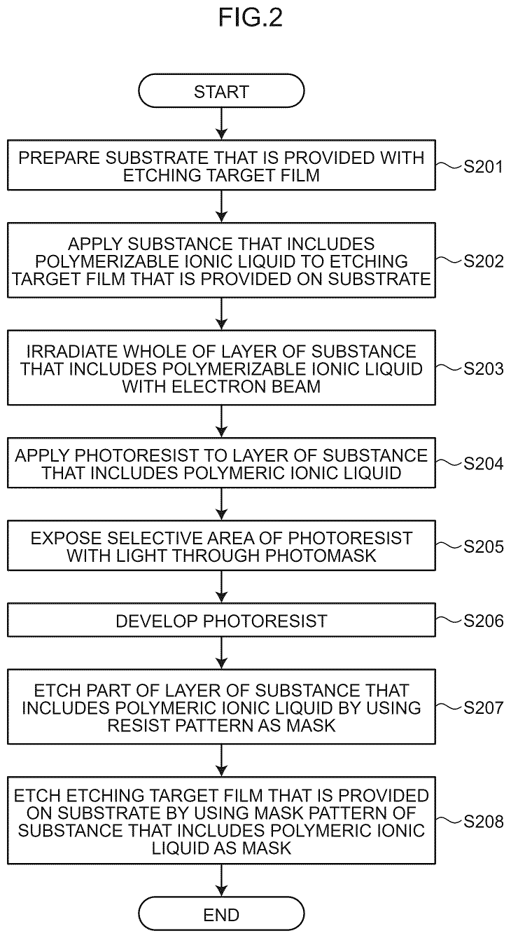

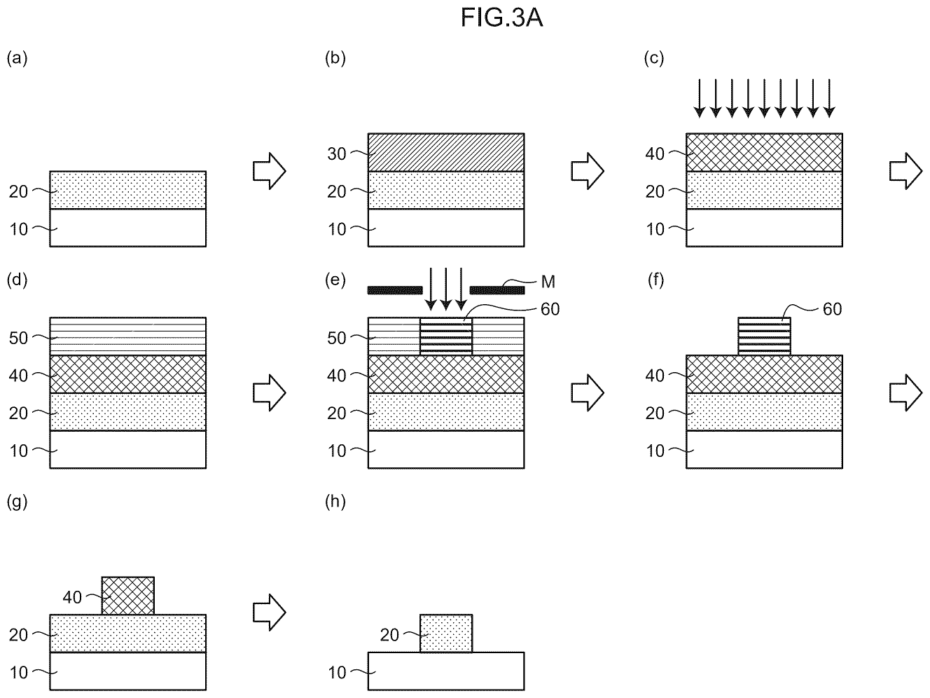

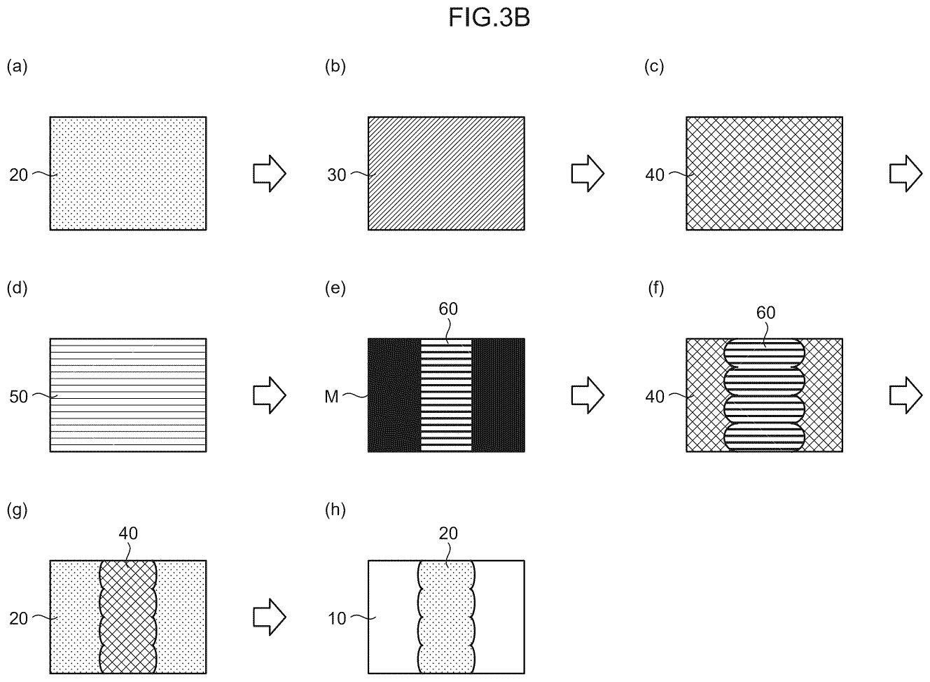

FIG. 2 is a flowchart that illustrates a first example of a substrate processing method according to an embodiment. FIG. 3A and FIG. 3B are schematic diagrams that explain a first example of a substrate processing method according to an embodiment. FIG. 3A illustrates a state of a substrate as viewed from a direction along a surface of such a substrate, in a first example of a substrate processing method. FIG. 3B illustrates a state of a substrate as viewed from a normal direction of a surface of such a substrate, in a first example of a substrate processing method.

First, at step S201 as illustrated in FIG. 2, a substrate 10 that is provided with an etching target film 20 is prepared as illustrated in (a) of FIG. 3A and (a) of FIG. 3B. Herein, the etching target film 20 is, for example, a film of silicon oxide and the substrate 10 is, for example, a silicon wafer. For example, tetraethoxysilane (TEOS) and an oxygen (O₂) gas are supplied to a silicon wafer, by, for example, a chemical vapor deposition (CVD) method, so that it is possible to form a film of silicon oxide on such a silicon wafer.

Then, at step S202 as illustrated in FIG. 2, a substance that includes a polymerizable ionic liquid 30 is applied to the etching target film 20 that is provided on the substrate 10, by, for example, a spin coating method, as illustrated in (b) of FIG. 3A and (b) of FIG. 3B. Thereby, a layer of the substance that includes a polymerizable ionic liquid 30 is formed on the etching target film 20 that is provided on the substrate 10. Additionally, a process at step S202 as illustrated in FIG. 2 corresponds to a process at step S101 as illustrated in FIG. 1.

Then, at step S203 as illustrated in FIG. 2, for example, a whole of a layer of the substance that includes a polymerizable ionic liquid 30 is irradiated with an electron beam, as illustrated in (c) of FIG. 3A and (c) of FIG. 3B. Thereby, a polymerization reaction of a polymerizable ionic liquid is caused for a whole of the substance that includes a polymerizable ionic liquid 30. Thus, a layer of a substance that includes a polymeric ionic liquid 40 is produced on the etching target film 20 that is provided on the substrate 10. Additionally, a process at step S203 as illustrated in FIG. 2 corresponds to a process at step S102 as illustrated in FIG. 1.

Then, at step S204 as illustrated in FIG. 2, a photoresist 50 is applied to a layer of the substance that includes a polymeric ionic liquid 40, as illustrated in (d) of FIG. 3A and (d) of FIG. 3B. The photoresist 50 is not particularly limited and may be, for example, a chemical-amplification-type resist.

Then, at step S205 as illustrated in FIG. 2, a selective area of the photoresist 50 is exposed to light through a photomask M, as illustrated in (e) of FIG. 3A and (e) of FIG. 3B. Thereby, a pattern of the photomask M is transferred to the photoresist 50 as a resist pattern 60. Additionally, for a method of light exposure, utilization of KrF excimer laser light, EUV light, etc., is provided.

Then, at step S206 as illustrated in FIG. 2, the photoresist 50 is developed, as illustrated in (f) of FIG. 3A and (f) of FIG. 3B. That is, the photoresist 50 in an area that is not exposed to light other than a selective area is removed. For a method of development, for example, dip development, etc., is/are provided. Additionally, after the photoresist 50 is developed, post-bake thereof may be executed. Thus, the resist pattern 60 is formed on a layer of the substance that includes a polymeric ionic liquid 40.

Herein, a roughness of the resist pattern 60 may be relatively large as illustrated in (f) of FIG. 3B. In particular, in a case where the photoresist 50 is exposed to EUV light at step S205, a roughness of the resist pattern 60 tends to be large.

Then, at step S207 as illustrated in FIG. 2, a part of a layer of the substrate that includes a polymeric ionic liquid 40 is etched by using the resist pattern 60 as a mask, as illustrated in (g) of FIG. 3A and (g) of FIG. 3B. For a method of etching, for example, dry etching that uses a plasma of a gas that includes oxygen, etc., is/are provided. Thereby, a mask pattern of the substance that includes a polymeric ionic liquid 40 is formed on the etching target film 20 that is provided on the substrate 10. Additionally, processes at steps S204, S205, S206, and S207 as illustrated in FIG. 2 correspond to a process at step S103 as illustrated in FIG. 1.

Herein, as illustrated in (g) of FIG. 3B, a roughness of a mask pattern of the substance that includes a polymeric ionic liquid 40 is relatively small due to a self-restoring property of a polymeric ionic liquid. More specifically, when a part of a layer of the substance that includes a polymeric ionic liquid 40 is etched, a relatively large roughness of the resist pattern 60 may be transferred to a mask pattern of the substance that includes a polymeric ionic liquid 40. However, a polymer chain(s) near a damage(s) or an irregularity(ies) on a surface of a mask pattern of the substance that includes a polymeric ionic liquid 40 is/are restored due to a self-restoring property of a polymeric ionic liquid. Accordingly, an irregularity(ies) on a surface of a mask pattern of the substance that includes a polymeric ionic liquid 40 is/are reduced. As a result, it is considered that a roughness of a mask pattern is reduced. That is, it is possible to form a mask pattern of the substance that includes a polymeric ionic liquid 40, with a roughness that is smaller than a roughness of the resist pattern 60, on the etching target film 20 that is provided on the substrate 10. Thus, it is possible to reduce a roughness of a mask pattern. In particular, even in a case where the photoresist 50 is exposed to EUV light at step S205, it is possible to reduce a roughness of a mask pattern.

Then, at step S208 as illustrated in FIG. 2, the etching target film 20 that is provided on the substrate 10 is etched by using a mask pattern of the substance that includes a polymeric ionic liquid 40 as a mask, as illustrated in (h) of FIG. 3A and (h) of FIG. 3B. For a method of etching, for example, in a case where the etching target film 20 is a film of silicon oxide, wet etching that uses hydrofluoric acid or dry etching that uses a plasma of a gas that includes fluorine, etc., is/are provided. Additionally, a process at step S208 as illustrated in FIG. 2 corresponds to a process at step S104 as illustrated in FIG. 1.

Herein, as illustrated in (g) of FIG. 3B, a roughness of the etching target film 20 that has been etched is comparable with a roughness of a mask pattern of the substance that includes a polymeric ionic liquid 40. That is, it is possible to transfer a mask pattern of the substance that includes a polymeric ionic liquid 40, with a roughness that is smaller than a roughness of the resist pattern 60, to the etching target film 20 that is provided on the substrate 10. Thus, it is possible to reduce a roughness of a pattern that is transferred to the etching target film 20. In particular, even in a case where the photoresist 50 is exposed to EUV light at step S205, it is possible to reduce a roughness of a pattern that is transferred to the etching target film 20.

### Second Example of Substrate Processing Method

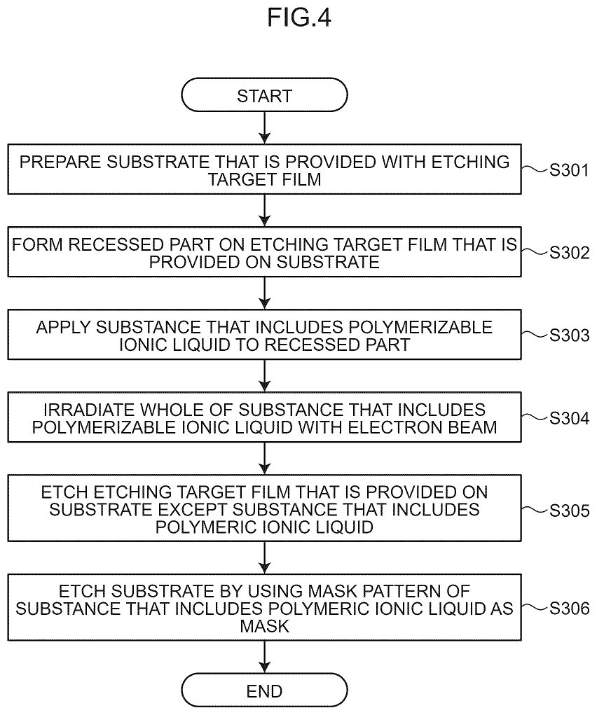

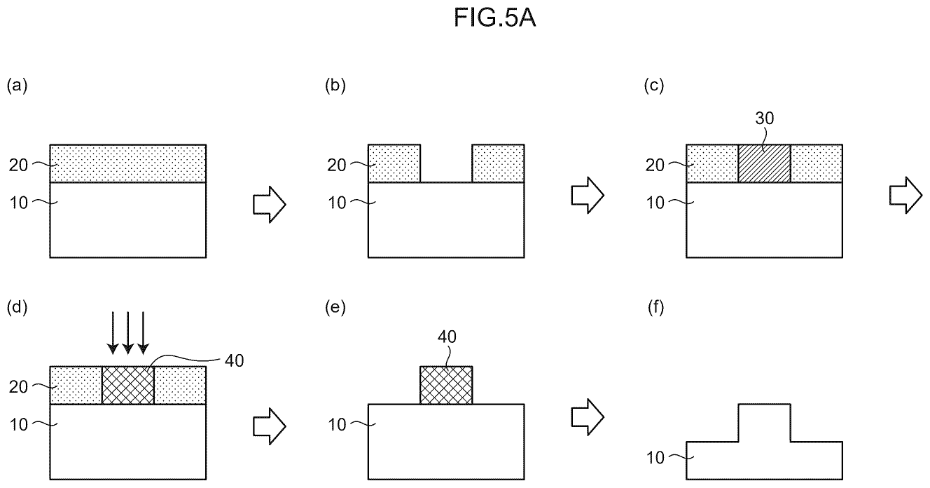

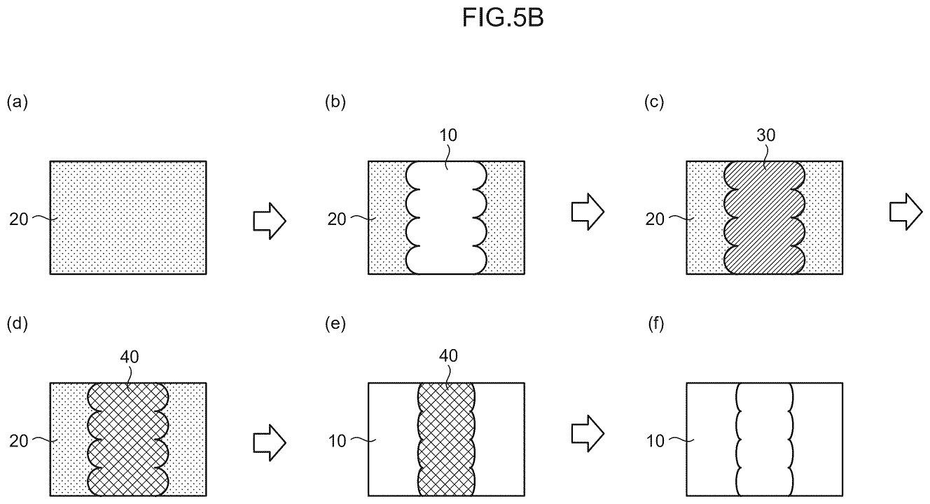

FIG. 4 is a flowchart that illustrates a second example of a substrate processing method according to an embodiment. FIG. 5A and FIG. 5B are schematic diagrams that explain a second example of a substrate processing method according to an embodiment. FIG. 5A illustrates a state of a substrate as viewed from a direction along a surface of such a substrate, in a second example of a substrate processing method. FIG. 5B illustrates a state of a substrate as viewed from a normal direction of a surface of such a substrate, in a second example of a substrate processing method.

First, at step S301 as illustrated in FIG. 4, a substrate 10 that is provided with an etching target film 20 is prepared as illustrated in (a) of FIG. 5A and (a) of FIG. 5B, similarly to step S201 as illustrated in FIG. 2. Herein, the etching target film 20 is, for example, a film of silicon oxide and the substrate 10 is, for example, a silicon wafer.

Then, at step S302 as illustrated in FIG. 4, a recessed part is formed on the etching target film 20 that is provided on the substrate 10 as illustrated in (b) of FIG. 5A and (b) of FIG. 5B. For a method that forms a recessed part on the etching target film 20, etching of the etching target film 20, etc., is/are provided. For a method of etching, for example, in a case where the etching target film 20 is a film of silicon oxide, wet etching that uses hydrofluoric acid or dry etching that uses a plasma of a gas that includes fluorine, etc., is/are provided. Additionally, a shape of a recessed part is not particularly limited.

Herein, as illustrated in (b) of FIG. 5B, a roughness of a recessed part that is formed on the etching target film 20 may be relatively large.

Then, at step S303 as illustrated in FIG. 4, a substance that includes a polymerizable ionic liquid 30 is applied to a recessed part, by, for example, a spin coating method, as illustrated in (c) of FIG. 5A and (c) of FIG. 5B. Thereby, the substance that includes a polymerizable ionic liquid 30 that is embedded in a recessed part is formed. Additionally, a process at step S303 as illustrated in FIG. 4 corresponds to a process at step S101 as illustrated in FIG. 1.

Then, at step S304 as illustrated in FIG. 4, for example, a whole of the substance that includes a polymerizable ionic liquid 30 is irradiated with an electron beam as illustrated in (d) of FIG. 5A and (d) of FIG. 5B. Thereby, a polymerization reaction of a polymerizable ionic liquid is caused for the substance that includes a polymerizable ionic liquid 30. Thus, a substance that includes a polymeric ionic liquid 40 that is embedded in a recessed part is produced. Additionally, a process at step S304 as illustrated in FIG. 4 corresponds to a process at step S102 as illustrated in FIG. 1.

Then, at step S305 as illustrated in FIG. 4, the etching target film 20 that is provided on the substrate 10 except the substance that includes a polymeric ionic liquid 40 is etched as illustrated in (e) of FIG. 5A and (e) of FIG. 5B. For a method of etching, for example, in a case where the etching target film 20 is a film of silicon oxide, wet etching that uses hydrofluoric acid or dry etching that uses a plasma of a gas that includes fluorine, etc., is/are provided. Thereby, a mask pattern of the substance that includes a polymeric ionic liquid 40 is formed on the substrate 10. Additionally, a process at step S305 as illustrated in FIG. 4 corresponds to a process at step S103 as illustrated in FIG. 1.

Herein, as illustrated in (e) of FIG. 5B, a roughness of a mask pattern of the substance that includes a polymeric ionic liquid 40 is relatively small due to a self-restoring property of a polymeric ionic liquid. More specifically, when the etching target film 20 that is provided on the substrate 10 is etched, a relatively large roughness of a recessed part that is formed on the etching target film 20 may be transferred to a mask pattern of the substance that includes a polymeric ionic liquid 40. However, a polymer chain(s) near a damage(s) or an irregularity(ies) on a surface of a mask pattern of the substance that includes a polymeric ionic liquid 40 is/are restored due to a self-restoring property of a polymeric ionic liquid. Accordingly, an irregularity(ies) on a surface of a mask pattern of the substance that includes a polymeric ionic liquid 40 is/are reduced. As a result, it is considered that a roughness of a mask pattern is reduced. That is, it is possible to form a mask pattern of the substance that includes a polymeric ionic liquid 40, with a roughness that is smaller than a roughness of a recessed part that is formed on the etching target film 20, on the substrate 10. Thus, it is possible to reduce a roughness of a mask pattern.

Then, at step S306 as illustrated in FIG. 4, the substrate 10 is etched by using a mask pattern of the substance that includes a polymeric ionic liquid 40 as a mask, as illustrated in (f) of FIG. 5A and (f) of FIG. 5B. Thereby, the substrate 10 that has a protruding part is formed. For a method of etching, for example, in a case where the substrate 10 is a silicon wafer, wet etching that uses an aqueous solution of potassium hydroxide (KOH) or dry etching that uses a plasma of a gas that includes fluorine or chlorine, etc., is/are provided. Additionally, a process at step S306 as illustrated in FIG. 4 corresponds to a process at step S104 as illustrated in FIG. 1.

Herein, as illustrated in (f) of FIG. 5B, a roughness of a protruding part of the substrate 10 that has been etched is comparable with a roughness of a mask pattern of the substance that includes a polymeric ionic liquid 40. That is, it is possible to transfer a mask pattern of the substance that includes a polymeric ionic liquid 40, with a roughness that is smaller than a roughness of a recessed part that is formed on the etching target film 20, to the substrate 10. Thus, it is possible to reduce a roughness of a pattern that is transferred to the substrate 10.

### Third Example of Substrate Processing Method

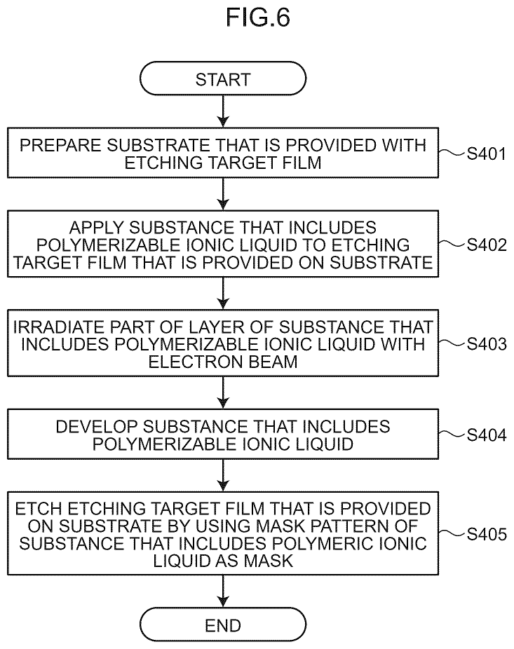

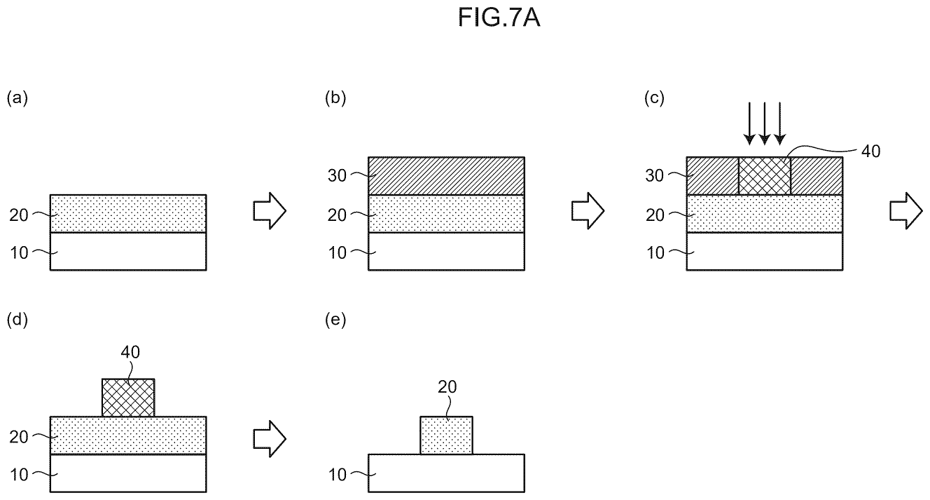

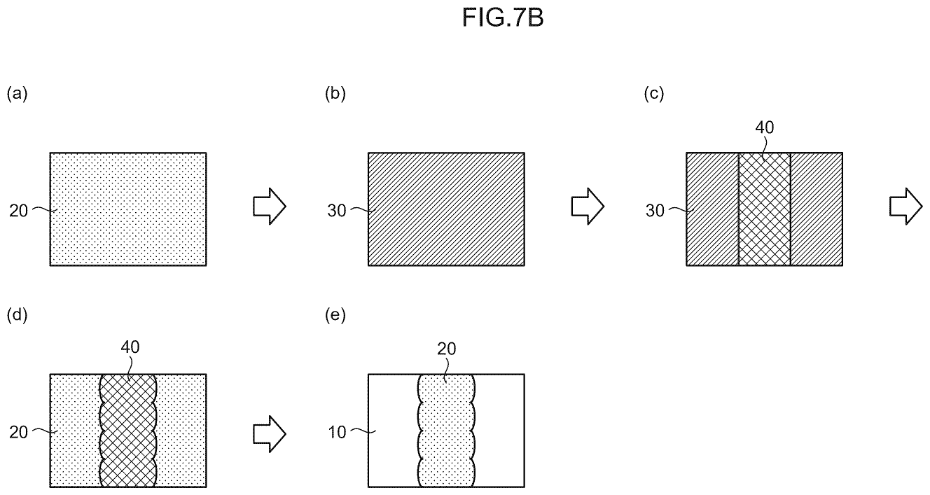

FIG. 6 is a flowchart that illustrates a third example of a substrate processing method according to an embodiment. FIG. 7A and FIG. 7B are schematic diagrams that explain a third example of a substrate processing method according to an embodiment. FIG. 7A illustrates a state of a substrate as viewed from a direction along a surface of such a substrate, in a third example of a substrate processing method. FIG. 7B illustrates a state of a substrate as viewed from a normal direction of a surface of such a substrate, in a third example of a substrate processing method.

First, at step S401 as illustrated in FIG. 6, a substrate 10 that is provided with an etching target film 20 is prepared as illustrated in (a) of FIG. 7A and (a) of FIG. 7B, similarly to step S201 as illustrated in FIG. 2 and step S301 as illustrated in FIG. 3. Herein, the etching target film 20 is, for example, a film of silicon oxide and the substrate 10 is, for example, a silicon wafer.

Then, at step S402 as illustrated in FIG. 6, a substance that includes a polymerizable ionic liquid 30 is applied to the etching target film 20 that is provided on the substrate 10, by, for example, a spin coating method, as illustrated in (b) of FIG. 7A and (b) of FIG. 7B. Thereby, a layer of a substance that includes a polymerizable ionic liquid 30 is formed on the substrate 10. Additionally, a process at step S402 as illustrated in FIG. 6 corresponds to a process at step S101 as illustrated in FIG. 1.

Then, at step S403 as illustrated in FIG. 6, for example, a part of a layer of the substance that includes a polymerizable ionic liquid 30 is irradiated with an electron beam as illustrated in (c) of FIG. 7A and (c) of FIG. 7B. Thereby, a polymerization reaction of a polymerizable ionic liquid is caused for a part of the substance that includes a polymerizable ionic liquid 30. For example, a layer of the substance that includes a polymerizable ionic liquid 30 is scanned with an electron beam, so that a polymerization reaction of a polymerizable ionic liquid is caused in a selective area on a layer of the substance that includes a polymerizable ionic liquid 30. Thus, a substance that includes a polymeric ionic liquid 40 is produced on the etching target film 20 that is provided on the substrate 10. Additionally, a process at step S403 as illustrated in FIG. 6 corresponds to a process at step S102 as illustrated in FIG. 1.

Then, at step S404 as illustrated in FIG. 6, the substance that includes a polymerizable ionic liquid 30 is developed as illustrated in (d) of FIG. 7A and (d) of FIG. 7B. That is, the substance that includes a polymerizable ionic liquid 30 except the substance that includes a polymeric ionic liquid 40 is removed. For a method of development, for example, dip development that uses a solvent that dissolves a polymerizable ionic liquid, etc., is/are provided. Thus, a mask pattern of the substance that includes a polymeric ionic liquid 40 is formed on the etching target film 20 that is provided on the substrate 10. Additionally, a process at step S404 as illustrated in FIG. 6 corresponds to a process at step S103 as illustrated in FIG. 1.

Herein, as illustrated in (d) of FIG. 7B, a roughness of a mask pattern of the substance that includes a polymeric ionic liquid 40 is relatively small due to a self-restoring property of a polymeric ionic liquid. More specifically, when the substance that includes a polymerizable ionic liquid 30 is developed, a damage(s) or an irregularity(ies) may be produced on a surface of a mask pattern of the substance that includes a polymeric ionic liquid 40. However, a polymer chain(s) near a damage(s) or an irregularity(ies) on a surface of a mask pattern of the substance that includes a polymeric ionic liquid 40 is/are restored due to a self-restoring property of a polymeric ionic liquid. Accordingly, an irregularity(ies) on a surface of a mask pattern of the substance that includes a polymeric ionic liquid 40 is/are reduced. As a result, it is considered that a roughness of a mask pattern is reduced. That is, it is possible to form a mask pattern of the substance that includes a polymeric ionic liquid 40, with a relatively small roughness, on the substrate 10. Thus, it is possible to reduce a roughness of a mask pattern.

Then, at step S405 as illustrated in FIG. 6, the etching target film 20 that is provided on the substrate 10 is etched by using a mask pattern of the substance that includes a polymeric ionic liquid 40 as a mask, as illustrated in (e) of FIG. 7A and (e) of FIG. 7B. For a method of etching, for example, in a case where the etching target film 20 is a film of silicon oxide, wet etching that uses hydrofluoric acid or dry etching that uses a plasma of a gas that includes fluorine, etc., is/are provided. Additionally, a process at step S405 as illustrated in FIG. 6 corresponds to a process at step S104 as illustrated in FIG. 1.

Herein, as illustrated in (e) of FIG. 7B, a roughness of the etching target film 20 that has been etched is comparable with a roughness of a mask pattern of the substance that includes a polymeric ionic liquid 40. That is, it is possible to transfer a mask pattern of the substance that includes a polymeric ionic liquid 40, with a relatively small roughness, to the etching target film 20 that is provided on the substrate 10. Thus, it is possible to reduce a roughness of a pattern that is transferred to the etching target film 20.

### Substrate Processing System

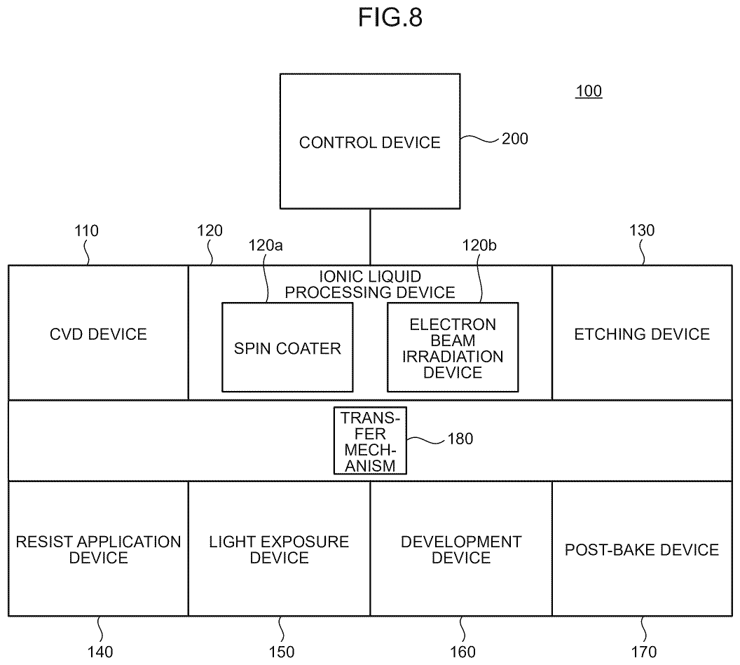

FIG. 8 is a diagram that schematically explains an example of a substrate processing system for implementing a substrate processing method according to an embodiment. A substrate processing system 100 as illustrated in FIG. 8 includes a CVD device 110, an ionic liquid processing device 120, an etching device 130, a resist application device 140, a light exposure device 150, a development device 160, a post-bake device 170, a transfer mechanism 180, and a control device 200.

The CVD device 110 is configured to provide a substrate 10 with an etching target film 20. For example, tetraethoxysilane (TEOS) and an oxygen (O₂) gas are supplied to a silicon wafer, so that a film of silicon oxide is formed on such a silicon wafer. The ionic liquid processing device 120 includes a spin coater 120a and an electron beam irradiation device 120b. The spin coater 120a is configured to apply a substance that includes a polymerizable ionic liquid 30 to a substrate 10 or an etching target film 20 that is provided on the substrate 10. The electron beam irradiation device 120b is configured to irradiate a layer of a substance that includes a polymerizable ionic liquid 30 with an electron beam, so that a substance that includes a polymeric ionic liquid 40 is produced. The etching device 130 is configured to etch a substrate 10, an etching target film 20, a layer of a substance that includes a polymeric ionic liquid 40, etc.

The resist application device 140 is configured to apply a photoresist 50 thereto. The light exposure device 150 is configured to expose a photoresist 50 to KrF excimer laser light, EUV light, etc., through a photomask. The development device 160 is configured to develop a substance that includes a polymerizable ionic liquid 30 or a photoresist 50. The post-bake device 170 is configured to bake a photoresist 50 after development of the photoresist 50.

The transfer mechanism 180 is configured to be capable of holding and moving a substrate 10 in the substrate processing system 100. Furthermore, the transfer mechanism 180 is configured to transfer a substrate 10 into and out of each of the CVD device 110, the ionic liquid processing device 120, the etching device 130, the resist application device 140, the light exposure device 150, the development device 160, and the post-bake device 170. The control device 200 controls the CVD device 110, the ionic liquid processing device 120, the etching device 130, the resist application device 140, the light exposure device 150, the development device 160, the post-bake device 170, and the transfer mechanism 180. Thereby, the control device 200 executes a substrate processing method according to an embodiment or a mask pattern formation method according to an embodiment. A configuration of the control device 200 will be described later.

Hereinafter, a practical example(s) of the present disclosure will be explained specifically. Additionally, the present disclosure is not limited to a practical example(s) as illustrated below.

A silicon wafer as a substrate that was provided with a film of silicon oxide (SiO₂) as an etching target film was prepared. A polymerizable ionic liquid was prepared that was composed of a cation (1-ethyl-3-vinylimidazolium) that was a monomer that was represented by a chemical formula of

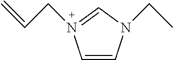

and an anion (bis(trifluoromethanesulfonyl)imide) that was represented by a chemical formula of

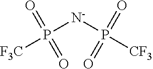

as a substance that included a polymerizable ionic liquid.

Then, the polymerizable ionic liquid was applied to a whole of a surface of the film of silicon oxide on the silicon wafer by spin coating, so as to form a film of a polymerizable ionic liquid on the film of silicon oxide.

Then, a plurality of linear areas on the film of a polymerizable ionic liquid were irradiated with an electron beam so as to cause polymerization reaction of the cation that was a monomer on the plurality of linear areas on the film of a polymerizable ionic liquid. Thus, a polymeric ionic liquid that was composed of a polymer of the cation and the anion was produced on the plurality of linear areas on the film of a polymerizable ionic liquid.

Then, the polymerizable ionic liquid on an area that was not irradiated with an electron beam was removed by using propylene glycol monomethyl ether acetate as a solvent for the polymerizable ionic liquid. Thereby, a mask pattern of the polymeric ionic liquid was formed on the film of silicon oxide. The mask pattern of the polymeric ionic liquid was a plurality of linear wall parts that had a varying width.

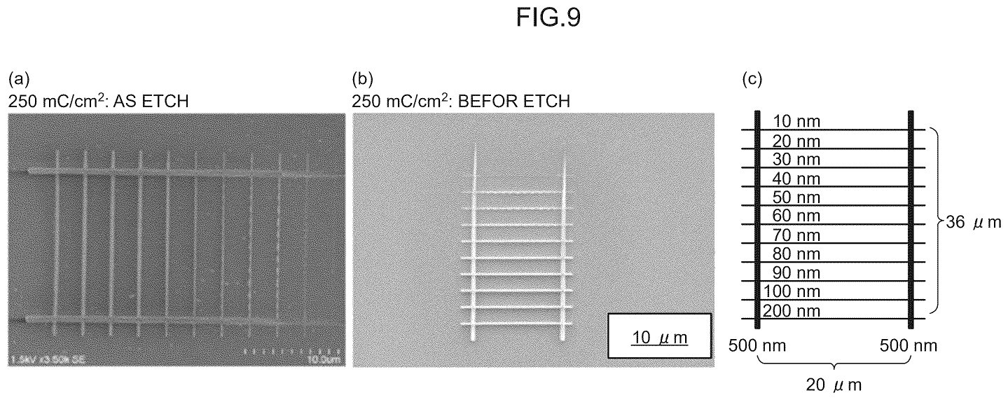

FIG. 9 is a diagram that illustrates an example of a mask pattern of a polymeric ionic liquid according to a practical example. (a) of FIG. 9 illustrates an example of a mask pattern of a polymeric ionic liquid after a plasma of a gas that included fluorine was applied thereto. Herein, application of a plasma of a gas that included fluorine assumed dry etching that used such a plasma of a gas that included fluorine. (b) of FIG. 9 illustrates an example of a mask pattern of a polymeric ionic liquid before a plasma of a gas that included fluorine was applied thereto. (c) of FIG. 9 illustrates a condition(s) for forming a mask pattern of a polymeric ionic liquid as illustrated in (a) of FIG. 9 and (b) of FIG. 9.

As illustrated in (c) of FIG. 9, first, a plurality of linear areas that had widths of 10 nm, 20 nm, 30 nm, 40 nm, 50 nm, 60 nm, 70 nm, 80 nm, 90 nm, 100 nm, and 200 nm on the film of a polymerizable ionic liquid were irradiated with an electron beam. Additionally, a distance between the plurality of linear areas was 3.6 μm. Then, two linear areas that were orthogonal to the plurality of linear areas as described above were irradiated with an electron beam. A width of and a distance between the two linear areas were 500 nm and 20 μm, respectively. Thus, a mask pattern of a polymeric ionic liquid as illustrated in (a) or (b) of FIG. 9 was formed.

Additionally, when the mask pattern of a polymeric ionic liquid as illustrated in (a) or (b) of FIG. 9 was formed, a rotational frequency for spin coating was set at 4000 revolutions per minute. An acceleration voltage, a beam current, and a dose amount of an electron beam were 30 kV, 1 nA, and 250 mC/cm², respectively. As illustrated in (a) and (b) of FIG. 9, in a case where at least a plurality of linear areas that had a width of 30 nm or greater were irradiated with an electron beam, it was possible to confirm formation of a mask pattern of a polymeric ionic liquid that was a plurality of linear wall parts.

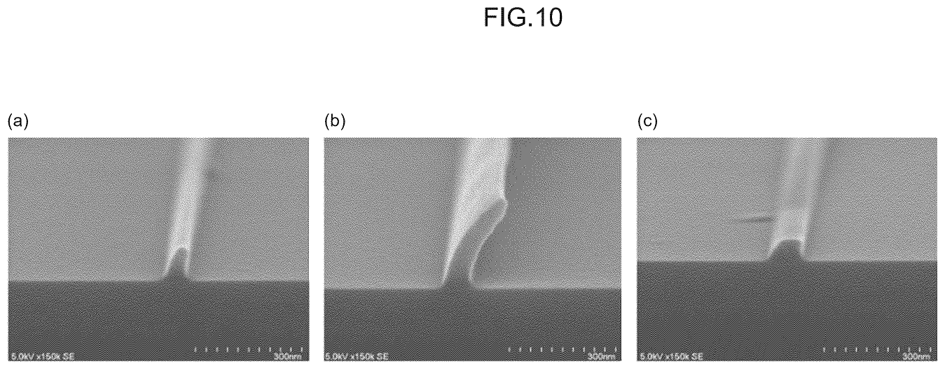

FIG. 10 is a diagram that illustrates an example of a mask pattern of a polymeric ionic liquid according to a practical example. A mask pattern of a polymeric ionic liquid as illustrated in FIG. 10 was formed, similarly to formation of the mask pattern of a polymeric ionic liquid as illustrated in (b) of FIG. 9. FIG. 10 illustrates a mask pattern of a polymeric ionic liquid before a plasma of a gas that included fluorine was applied thereto. (a) of FIG. 10 illustrates a mask pattern of a polymeric ionic liquid in a case where a linear area that had a width of 30 nm on a film of the polymerizable ionic liquid was irradiated with an electron beam. (b) of FIG. 10 illustrates a mask pattern of a polymeric ionic liquid in a case where a linear area that had a width of 40 nm on a film of the polymerizable ionic liquid was irradiated with an electron beam. (c) of FIG. 10 illustrates a mask pattern of a polymeric ionic liquid in a case where a linear area that had a width of 50 nm on a film of the polymerizable ionic liquid was irradiated with an electron beam.

Additionally, when the mask pattern of a polymeric ionic liquid as illustrated in (a), (b) or (c) of FIG. 10 was formed, a rotational frequency for spin coating was set at 6000 revolutions per minute. An acceleration voltage, a beam current, and a dose amount of an electron beam were 30 kV, 1 nA, and 550 mC/cm², respectively. As illustrated in (a), (b), and (c) of FIG. 10, in a case where a plurality of linear areas that had widths of 30 nm, 40 nm, and 50 nm were irradiated with an electron beam, it was possible to confirm formation of a mask pattern of a polymeric ionic liquid that was a plurality of linear wall parts. Furthermore, as illustrated in (a), (b), and (c) of FIG. 10, side walls of the mask pattern of a polymeric ionic liquid that was a plurality of linear wall parts were smooth. Hence, it was confirmed that an LER of a side wall of a mask pattern of a polymeric ionic liquid was small before application of dry etching that used a plasma of a gas that included fluorine. Thereby, it was confirmed that it was possible to reduce an LER of a side wall of a mask pattern by using a polymeric ionic liquid.

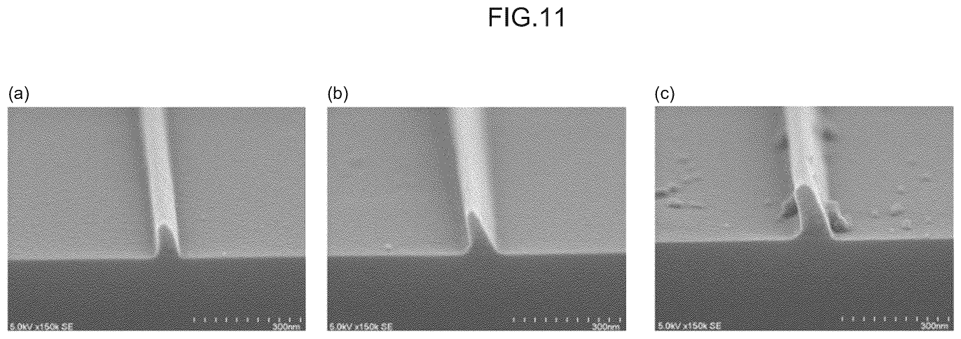

FIG. 11 is a diagram that illustrates an example of a mask pattern of a polymeric ionic liquid according to a practical example. A mask pattern of a polymeric ionic liquid as illustrated in FIG. 11 was formed, similarly to formation of the mask pattern of a polymeric ionic liquid as illustrated in (a) of FIG. 9. FIG. 11 illustrates a mask pattern of a polymeric ionic liquid after a plasma of a gas that included fluorine was applied thereto. (a) of FIG. 11 illustrates a mask pattern of a polymeric ionic liquid in a case where a linear area that had a width of 30 nm on a film of the polymerizable ionic liquid was irradiated with an electron beam. (b) of FIG. 11 illustrates a mask pattern of a polymeric ionic liquid in a case where a linear area that had a width of 40 nm on a film of the polymerizable ionic liquid was irradiated with an electron beam. (c) of FIG. 11 illustrates a mask pattern of a polymeric ionic liquid in a case where a linear area that had a width of 50 nm on a film of the polymerizable ionic liquid was irradiated with an electron beam.

Additionally, when the mask pattern of a polymeric ionic liquid as illustrated in (a), (b) or (c) of FIG. 11 was formed, a rotational frequency for spin coating was set at 5000 revolutions per minute. An acceleration voltage, a beam current, and a dose amount of an electron beam were 30 kV, 1 nA, and 550 mC/cm², respectively. As illustrated in (a), (b), and (c) of FIG. 11, in a case where a plurality of linear areas that had widths of 30 nm, 40 nm, and 50 nm were irradiated with an electron beam, it was possible to confirm formation of a mask pattern of a polymeric ionic liquid that was a plurality of linear wall parts. Furthermore, as illustrated in (a), (b), and (c) of FIG. 11, side walls of the mask pattern of a polymeric ionic liquid that was a plurality of linear wall parts were smooth. Hence, it was confirmed that an LER of a side wall of a mask pattern of a polymeric ionic liquid was small even after application of dry etching that used a plasma of a gas that included fluorine. Thereby, it was confirmed that it was possible to reduce an LER of a side wall of a mask pattern by using a polymeric ionic liquid.

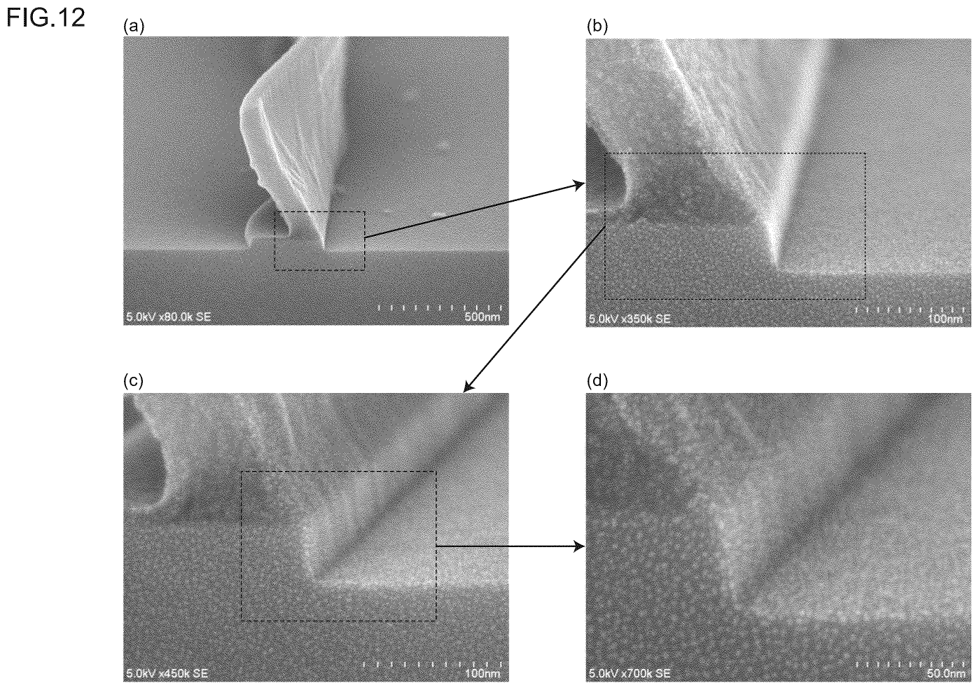

FIG. 12 is a diagram that illustrates an example of a mask pattern of a polymeric ionic liquid according to a practical example. A mask pattern of a polymeric ionic liquid as illustrated in FIG. 12 was formed, similarly to formation of the mask pattern of a polymeric ionic liquid as illustrated in (a) of FIG. 9. FIG. 12 illustrates an example of a mask pattern of a polymeric ionic liquid after dry etching that used a plasma of a gas that included fluorine was applied to the film of silicon oxide. Additionally, (b) of FIG. 12 is an enlarged view of a dotted line region in (a) of FIG. 12, (c) of FIG. 12 is an enlarged view of a dotted line region in (b) of FIG. 12, and (d) of FIG. 12 is an enlarged view of a dotted line region in (c) of FIG. 12.

As illustrated in FIG. 12, not only side walls of the mask patten of a polymeric ionic liquid that was a plurality of linear wall parts but also side surfaces of an etched film of silicon oxide were smooth. Hence, it was confirmed that such a smooth mask pattern of a polymeric ionic liquid was transferred to a film of silicon oxide after application of dry etching that used a plasma of a gas that included fluorine. Thereby, it was confirmed that it was possible to reduce not only an LER of a side wall of a mask pattern but also an LER of a film of silicon oxide, by using a polymeric ionic liquid.

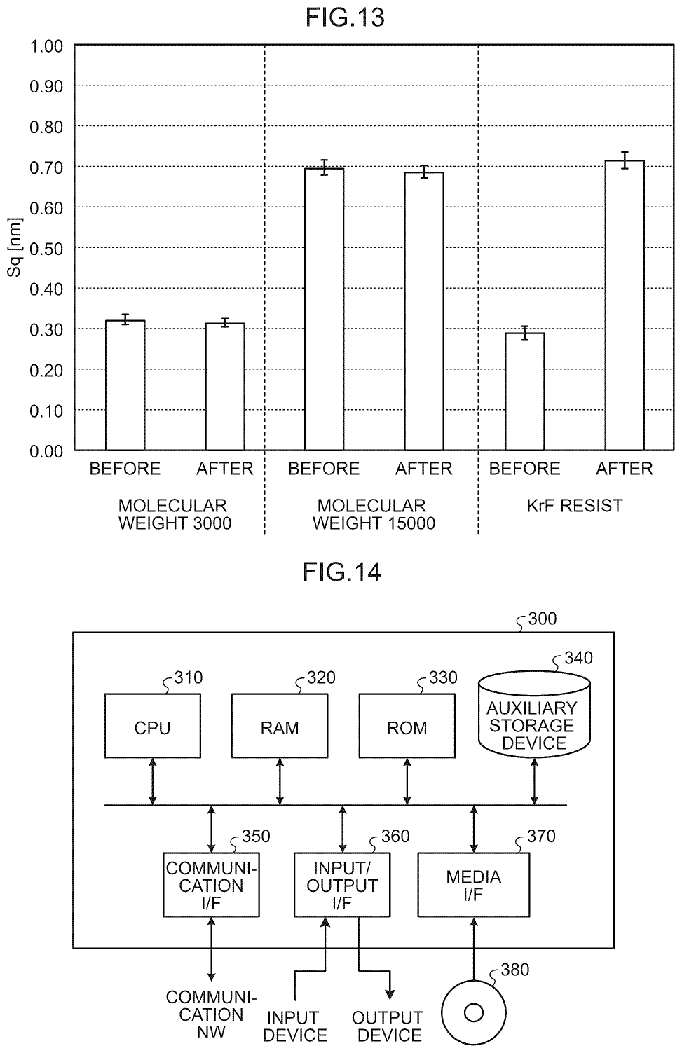

FIG. 13 is a diagram that illustrates an example of LERs of a mask pattern according to a practical example and a mask pattern according to a comparative example. In FIG. 13, molecular weight 3000 indicates a mask pattern according to a practical example where an average molecular weight of a polymeric ionic liquid was about 3000. Molecular weight 15000 indicates a mask pattern according to a practical example where an average molecular weight of a polymeric ionic liquid was about 15000. KrF resist indicates a conventional resist according to a comparative example. Furthermore, before and after mean before and after application of dry etching that used a plasma of a gas that included fluorine, respectively. A vertical axis of FIG. 13 indicates a value (nm) of Sq (root mean square roughness) as an LER of a mask pattern.

As illustrated in FIG. 13, a value of Sq of a mask pattern according to a practical example was little changed between before and after application of dry etching that used a plasm of a gas that included fluorine, for any of molecular weight 3000 and molecular weight 15000. That is, it was confirmed that an LER of a mask pattern according to a practical example was maintained even after dry etching that used a plasm of a gas that included fluorine.

As illustrated in FIG. 13, a value of Sq of a mask pattern according to a comparative example was increased, with respect to before application of dry etching that used a plasm of a gas that included fluorine, after such dry etching. That is, it was confirmed that an LER of a mask pattern according to a comparative example was increased after dry etching that used a plasm of a gas that included fluorine.

### Hardware Configuration of Computer

The control device 200 that is included in the substrate processing system 100 as illustrated in FIG. 8 is realized by, for example, a computer 300 as illustrated in FIG. 14. FIG. 14 is a diagram that illustrates an example of a hardware configuration of a computer 300 that composes the control device 200 that is included in the substrate processing system 100. The computer 300 includes a CPU (Central Processing Unit) 310, an RAM (Random Access Memory) 320, an ROM (Read Only Memory) 330, and an auxiliary storage device 340. Furthermore, the computer 300 includes a communication interface (I/F) 350, an input/output interface (I/F) 360, and a media interface (I/F) 370.

The CPU 310 is operated based on a program that is stored in the ROM 330 or the auxiliary storage device 340 so as to execute control of each unit. The ROM 330 stores a boot program that is executed by the CPU 310 at a time of a start of the computer 300, a program that depends on hardware of the computer 300, etc.

The auxiliary storage device 340 is, for example, an HDD (Hard Disk Drive) or an SSD (Solid State Drive), etc., and stores a program that is executed by the CPU 310 and data that are used by such a program, etc. The CPU 310 reads such a program from the auxiliary storage device 340, loads it on the RAM 320, and executes such a loaded program. The communication I/F 350 receives a signal and/or data from the ionic liquid processing device 120, the etching device 130, etc., and sends it/them to the CPU 310, through a communication NW (Net Work) such as a LAN (Local Area Network). Furthermore, the communication I/F 350 transmits a signal and/or data that is/are produced by the CPU 310 to the ionic liquid processing device 120, the etching device 130, etc., through the communication NW.

The CPU 310 controls an input device and an output device through the input/output I/F 360. The CPU 310 acquires a signal that is input from an input device and sends it to the CPU 310, through the input/output I/F 360. Furthermore, the CPU 310 outputs produced data to an output device through the input/output I/F 360.

The media I/F 370 reads a program or data that is/are stored in a recording medium 380 and stores it/them in the auxiliary storage device 340. The recording medium 380 is, for example, an optical recording medium such as a DVD (Digital Versatile Disc) or a PD (Phase change rewritable Disk), a magnetooptical recording medium such as an MO (Magneto-Optical disk), a tape medium, a magnetic recording medium, or a semiconductor memory, etc.

The CPU 310 of the computer 300 executes a program that is loaded on the RAM 320 so as to realize each process as illustrated in a flowchart of FIG. 1, FIG. 2, FIG. 4, or FIG. 6. The CPU 310 of the computer 300 reads a program that is loaded on the RAM 320, from the recording medium 380, and stores it in the auxiliary storage device 340. As another example, the CPU 310 of the computer 300 may acquire a program from another device through the communication NW and store it in the auxiliary storage device 340.

An aspect of an embodiment provides a technique that is capable of reducing a roughness of a mask pattern.

A mask pattern formation method according to an aspect of an embodiment includes an application step, a polymerization step, and a mask pattern formation step. The application step applies a substance that includes a polymerizable ionic liquid to a substrate. The polymerization step causes a polymerization reaction of the polymerizable ionic liquid for at least a part of the substance that includes a polymerizable ionic liquid so as to produce a substance that include a polymeric ionic liquid on the substrate. The mask pattern formation step forms a mask pattern of the substance that includes a polymeric ionic liquid on the substrate by using the substance that includes a polymeric ionic liquid.

According to an aspect of an embodiment, it is possible to reduce a roughness of a mask pattern.

Additionally, it should be considered that an embodiment(s) that is/are disclosed herein is/are not limitative but is/are illustrative in all aspects thereof. In fact, it is possible to implement an embodiment(s) as described above in a variety of forms thereof. Furthermore, an embodiment(s) as described above may be omitted, substituted, and/or modified in various forms thereof, without departing from an attached claim(s) and an essence(s) thereof.

Furthermore, for an embodiment(s) as described above, an appendix/appendices as provided below is/are further disclosed.

### APPENDIX 1

A mask pattern formation method, including:
an application step that applies a substance that includes a polymerizable ionic liquid to a substrate;
a polymerization step that causes a polymerization reaction of the polymerizable ionic liquid for at least a part of the substance that includes a polymerizable ionic liquid so as to produce a substance that include a polymeric ionic liquid on the substrate; and
a mask pattern formation step that forms a mask pattern of the substance that includes a polymeric ionic liquid on the substrate by using the substance that includes a polymeric ionic liquid.

### APPENDIX 2

The mask pattern formation method according to appendix 1, wherein
the application step includes applying a substance that includes a polymerizable ionic liquid to the substrate so as to form a layer of the substance that includes a polymerizable ionic liquid on the substrate,
the polymerization step includes causing a polymerization reaction of the polymerizable ionic liquid for the substance that includes a polymerizable ionic liquid so as to produce a layer of a substance that includes a polymeric ionic liquid on the substrate, and
the mask pattern formation step includes forming a resist pattern on a layer of the substance that includes a polymeric ionic liquid, and etching a part of a layer of the substance that includes a polymeric ionic liquid by using the resist pattern as a mask so as to form a mask pattern of the substance that includes a polymeric ionic liquid on the substrate.

### APPENDIX 3

The mask pattern formation method according to appendix 1, further including
a recessed part formation step that forms a recessed part on the substrate, wherein
the application step includes applying a substance that includes a polymerizable ionic liquid to the recesses part so as to form a substance that includes a polymerizable ionic liquid that is embedded in the recessed part,
the polymerization step includes causing a polymerization reaction of the polymerizable ionic liquid for the substance that includes a polymerizable ionic liquid so as to produce a substance that includes a polymeric ionic liquid that is embedded in the recessed part, and
the mask pattern formation step includes etching a part of the substrate except the substance that includes a polymeric ionic liquid so as to form a mask pattern of the substance that includes a polymeric ionic liquid on the substrate.

### APPENDIX 4

The mask pattern formation method according to appendix 1, wherein
the application step includes applying a substance that includes a polymerizable ionic liquid to the substrate so as to form a layer of the substance that includes a polymerizable ionic liquid on the substrate,
the polymerization step includes causing a polymerization reaction of the polymerizable ionic liquid for a part of the substance that includes a polymerizable ionic liquid so as to produce a substance that includes a polymeric ionic liquid on the substrate, and
the mask pattern formation step includes developing the substance that includes a polymerizable ionic liquid so as to form a mask pattern of the substance that includes a polymeric ionic liquid on the substrate.

### APPENDIX 5

The mask pattern formation method according to any one of appendices 1 to 4, wherein
the substance that includes a polymerizable ionic liquid includes a solvent for the polymerizable ionic liquid, and
the substance that includes a polymeric ionic liquid includes the solvent.

### APPENDIX 6

The mask pattern formation method according to any one of appendices 1 to 5, wherein
the polymerization step includes irradiating the substance that includes a polymerizable ionic liquid with light or an electron beam so as to cause a polymerization reaction of the polymerizable ionic liquid for the substance that includes a polymerizable ionic liquid.

### APPENDIX 7

The mask pattern formation method according to any one of appendices 1 to 6, wherein
the application step includes applying the substance that includes a polymerizable ionic liquid to the substrate by spin coating.

### APPENDIX 8

A substrate processing method, including:
the mask pattern formation method according to any one of appendices 1 to 7; and
a substrate etching step that etches the substrate by using a mask pattern of the substance that includes a polymeric ionic liquid as a mask.

What is claimed is:

1. A mask pattern formation method, comprising:
applying a substance that includes a polymerizable ionic liquid to a substrate;
causing a polymerization reaction of the polymerizable ionic liquid for at least a part of the substance that includes a polymerizable ionic liquid to produce a substance that include a polymeric ionic liquid on the substrate; and
forming a mask pattern of the substance that includes a polymeric ionic liquid on the substrate by using the substance that includes a polymeric ionic liquid.

2. The mask pattern formation method according to claim 1, wherein
the applying includes applying a substance that includes a polymerizable ionic liquid to the substrate to form a layer of the substance that includes a polymerizable ionic liquid on the substrate,
the causing a polymerization reaction includes causing a polymerization reaction of the polymerizable ionic liquid for the substance that includes a polymerizable ionic liquid to produce a layer of a substance that includes a polymeric ionic liquid on the substrate, and
the forming a mask pattern includes forming a resist pattern on a layer of the substance that includes a polymeric ionic liquid, and etching a part of a layer of the substance that includes a polymeric ionic liquid by using the resist pattern as a mask to form a mask pattern of the substance that includes a polymeric ionic liquid on the substrate.

3. The mask pattern formation method according to claim 1, further comprising
forming a recessed part on the substrate, wherein
the applying includes applying a substance that includes a polymerizable ionic liquid to the recesses part to form a substance that includes a polymerizable ionic liquid that is embedded in the recessed part,
the causing a polymerization reaction includes causing a polymerization reaction of the polymerizable ionic liquid for the substance that includes a polymerizable ionic liquid to produce a substance that includes a polymeric ionic liquid that is embedded in the recessed part, and
the forming a mask pattern includes etching a part of the substrate except the substance that includes a polymeric ionic liquid to form a mask pattern of the substance that includes a polymeric ionic liquid on the substrate.

4. The mask pattern formation method according to claim 1, wherein
the applying includes applying a substance that includes a polymerizable ionic liquid to the substrate to form a layer of the substance that includes a polymerizable ionic liquid on the substrate,
the causing a polymerization reaction includes causing a polymerization reaction of the polymerizable ionic liquid for a part of the substance that includes a polymerizable ionic liquid to produce a substance that includes a polymeric ionic liquid on the substrate, and
the forming a mask pattern includes developing the substance that includes a polymerizable ionic liquid to form a mask pattern of the substance that includes a polymeric ionic liquid on the substrate.

5. The mask pattern formation method according to claim 1, wherein
the substance that includes a polymerizable ionic liquid includes a solvent for the polymerizable ionic liquid, and
the substance that includes a polymeric ionic liquid includes the solvent.

6. The mask pattern formation method according to claim 1, wherein
the causing a polymerization reaction includes irradiating the substance that includes a polymerizable ionic liquid with light or an electron beam to cause a polymerization reaction of the polymerizable ionic liquid for the substance that includes a polymerizable ionic liquid.

7. The mask pattern formation method according to claim 1, wherein
the applying includes applying the substance that includes a polymerizable ionic liquid to the substrate by spin coating.

8. A substrate processing method, comprising:
the mask pattern formation method according to claim 1; and
etching the substrate by using a mask pattern of the substance that includes a polymeric ionic liquid as a mask.
